(19) United States
(12) Patent Application Publication
(10) Pub. No.: US 2019/0145641 A1
(43) Pub. Date: May 16, 2019

(54) METHOD FOR MANUFACTURING SEMICONDUCTOR

(71) Applicant: SINFONIA TECHNOLOGY CO., LTD., Tokyo (JP)

(72) Inventors: Yasushi Taniyama, Tokyo (JP); Mitsutoshi Ochiai, Tokyo (JP); Mitsuo Natsume, Tokyo (JP); Atsushi Suzuki, Tokyo (JP)

(73) Assignee: SINFONIA TECHNOLOGY CO., LTD., Tokyo (JP)

(21) Appl. No.: 16/244,490

(22) Filed: Jan. 10, 2019

Related U.S. Application Data
(62) Division of application No. 14/269,360, filed on May 5, 2014.

(30) Foreign Application Priority Data
Jul. 16, 2013 (JP) 2013-147207

(51) Int. Cl. F24F 9/00; H01L 21/677; H01L 21/67

(52) U.S. Cl. CPC F24F 9/00; F24F 3/161; H01L 21/67017; H01L 21/67772

(57) ABSTRACT

There is provided a method for manufacturing semiconductor. The method includes providing a semiconductor manufacturing apparatus and providing an EFEM. The EFEM includes a shield gas curtain apparatus 6 that forms a gas curtain capable of shielding an opening 23 when an internal space 5S of a purge container 5, in which the humidity is reduced to a predetermined value by means of a bottom purge apparatus 25 provided in a load port 2, is brought into communication with an internal space 3S of a wafer transport chamber 3, the gas curtain being formed of a shield curtain gas blown immediately downward from a location near the opening 23 of the load port 2 and being closer to the wafer transport chamber 3 than the opening 23 at a higher height than an upper edge of the opening 23.

### CROSS-REFERENCE TO RELATED APPLICATION

The application is a Divisional of U.S. patent application Ser. No. 14/269,360, filed on May 5, 2014, which claims a priority of Japanese Application No. 2013-147207 filed on Jul. 16, 2013.

### BACKGROUND OF THE INVENTION

### Field of the Invention

The present invention relates to an EFEM composed of a wafer transport chamber and a load port, and to a load port.

### Description of the Related Art

In a semiconductor manufacturing process, wafers are processed in a clean room to improve yield and quality. Today, however, when the trends of high integration of devices and circuit miniaturization along with the adoption of larger wafers have progressed, it has become difficult to manage small dusts in an entire clean room in view of costs as well as from a technical point of view. Accordingly, instead of increasing the cleanliness of the entire interior of such a clean room, a system that incorporates “mini-environment system,” which locally increases the cleanliness only around wafers, has been adopted recently for transporting and otherwise processing wafers. The mini-environment system includes a storage container known as a Front-Opening Unified Pod (FOUP) for transporting and retaining a wafer in a highly clean environment. Such a FOUP constitutes an Equipment Front End Module (EFEM) in combination with a wafer transport chamber. In addition, a load port is used as important equipment, which functions as an interface for allowing a FOUP to exchange a wafer with the wafer transport chamber and for passing/receiving a FOUP itself to/from a FOUP transport apparatus.

The load port is provided with a door section, which is brought into close contact with a lid provided in a front face of the FOUP. The door section and the lid are opened at the same time while in close contact with each other, and a wafer transport robot such as an arm robot provided in the wafer transport chamber can unload a wafer in the FOUP into the wafer transport chamber and store a wafer in the FOUP through the load port from the wafer transport chamber. A module consisting of the wafer transport chamber, which provides a space including such a wafer transport robot located therein, along with the load port is referred to as an EFEM.

As miniaturization of semiconductor devices on a wafer or the like progresses, there is growing concern about quality degradation due not only to contamination but also to moisture adhered on a wafer in these days, leading to a necessity of keeping a clean and low humidity environment around wafers.

Accordingly, as a technique of injecting a predetermined gas into a FOUP to replace the atmosphere in the FOUP with the predetermined gas for providing a low humidity environment inside the FOUP, Japanese Patent Laid-Open No. 2007-180516 discloses a load port including a purge apparatus that opens a lid of a FOUP at a door section of the load port and blows a predetermined gas (e.g., nitrogen or inert gas) into the FOUP by a purge section provided closer to the wafer transport chamber than the opening while internal spaces of the FOUP and the wafer transport chamber communicate with each other through the opening of the load port.

Such a purge apparatus using a so-called front purge system, which injects a predetermined gas from the front (the side facing the door section of the load port) into a FOUP and replaces the atmosphere in the FOUP with the predetermined gas, allows the purging to be performed only while the lid of the FOUP is opened at the door section of the load port.

Japanese Patent Laid-Open No. 2011-187539 discloses a load port including a purge apparatus that injects a predetermined gas (e.g., nitrogen or inert gas) into a FOUP loaded with wafers placed on a table of the load port from the bottom to fill the FOUP and replace the atmosphere in the FOUP with the predetermined gas. The purge apparatus using a so-called bottom purge system, which injects gas such as nitrogen or dry air from the bottom of a FOUP into the FOUP and replaces the atmosphere in the FOUP with the predetermined gas, has an advantage over a purge apparatus using a front purge system that allows the purging to be performed only while the lid of the FOUP is opened at the door section of the load port in that the purging can be performed even while the lid of the FOUP is not opened at the door section of the load port. In addition, since the purging can be started upon receiving a FOUP at the load port from a transport apparatus such as an OHT (Overhead Hoist Transfer), the apparatus using a bottom purge system is advantageous over the one using a front purge system in that a higher maximum concentration of the predetermined gaseous atmosphere can be reached.

Furthermore, immediately after a FOUP is received from a transport apparatus such as an OHT at the load port, the bottom purging can be performed to replace the atmosphere in the FOUP with the predetermined gas, so that at least the humidity in the FOUP is reduced to a predetermined value or lower to keep a low humidity environment around wafers. In this way, quality degradation due to the moisture adherence on a wafer can be prevented or suppressed.

It has been found that when the lid of the FOUP is opened at the door section of the load port while a low humidity environment is maintained inside the FOUP, which is a purge container, once the bottom purging is performed to replace the atmosphere in the FOUP with the predetermined gas, the internal space of the FOUP is brought into communication with that of the wafer transport chamber through the opening of the load port, and the gaseous atmosphere in the wafer transport chamber enters the internal space of the FOUP, which may result in a rapid increase in the humidity in the FOUP.

Such a rapid increase in the humidity in the FOUP, which has once been reduced by the bottom purging down to a predetermined value or lower in order to secure a low humidity environment, may increase the possibility of moisture being adhered on a wafer and lead to a potential degradation of quality. Accordingly, there would be a need for a mechanism for reducing the humidity in the FOUP as necessary. It has also been found that the oxygen concentration in the FOUP shows the same trend as the humidity; if the oxygen concentration in the FOUP increases when the lid of the FOUP is opened, an oxide film may disadvantageously be formed on the wafer. Accordingly, the oxygen concentration in the FOUP could also be reduced by a mechanism for reducing the humidity in the FOUP as necessary.

Japanese Patent Laid-Open No. 2007-180516 discloses a technique of forming a gas curtain for closing the plane of the opening by discharging an inert gas from a curtain nozzle arranged on the upper portion of the opening at the same time as the front purging. According to the technique, stated advantages are that a gas entering a pod from outside the pod is suppressed by the gas curtain and that the concentration of an inert gas in the pod is maintained by supplying the inert gas into the pod. It is disclosed that the advantages can be combined to continuously maintain a partial pressure of an oxidizing gas in the pod at a predetermined low pressure even while the pod is opened.

However, since the front purging disclosed in Japanese Patent Laid-Open No. 2007-180516 can be performed only while the lid of the FOUP is opened at the door section of the load port, it has a disadvantage of a maximum concentration of gaseous atmosphere being lower than that reachable by the bottom purging. Even though such a relatively lower maximum concentration of gaseous atmosphere can be maintained, a relatively higher maximum concentration of gaseous atmosphere, as can be reached by the bottom purging, cannot be maintained, so that it is not expected to completely eliminate the possibility of moisture being adhered on a wafer in the gaseous atmosphere in the FOUP, which leads to a potential degradation of quality.

The present invention has been made in consideration of the above-described problems, and a main object thereof is to provide an EFEM and a load port, which adopt a bottom purge system capable of purging leading to a high maximum concentration of a predetermined gaseous atmosphere, while preventing and suppressing a rapid increase in at least the humidity in a purge container occurring immediately after a lid of the purge container is opened and the internal space of the purge container is brought into communication with that of a wafer transport chamber, so that quality degradation due to the moisture adhered on a wafer can be avoided.

### SUMMARY OF THE INVENTION

The present invention relates to an EFEM including a wafer transport chamber and a load port adjacent to the wafer transport chamber. In the EFEM according to the present invention, the load port includes a bottom purge apparatus capable of replacing a gaseous atmosphere in a purge container with a purge gas composed of nitrogen or dry air from the bottom side of the purge container. The EFEM further includes a shield gas curtain apparatus that forms a gas curtain capable of shielding an opening of the load port when an internal space of the purge container, in which at least humidity is reduced to a predetermined value by supplying the purge gas from the bottom purge apparatus, is brought into communication with an internal space of the wafer transport chamber through the opening, the gas curtain being formed of a shield curtain gas composed of nitrogen or dry air blown immediately downward or obliquely downward such that the gas diverges from the purge container, from a location near the opening and being closer to the wafer transport chamber than the opening at the same height as or a higher height than an upper edge of the opening.

The EFEM thus configured can perform purging leading to a high maximum concentration of a predetermined gaseous atmosphere by the bottom purge apparatus so as to maintain a low humidity at or below a predetermined value in the purge container. Even when the internal space of the purge container is in communication with that of the wafer transport chamber, a gas curtain that shields the opening of the load port can be formed by the shield gas curtain apparatus to prevent and suppress the entrance of the gaseous atmosphere in the wafer transport chamber into the purge container. Consequently, even after the internal space of the purge container is in communication with that of the wafer transport chamber, a low humidity can be maintained in the purge container and a rapid increase in the humidity in the purge container can be avoided. According to the EFEM of the present invention, which is capable of thus maintaining a low humidity in the purge container, adherence of moisture onto a wafer in the purge container can be prevented and suppressed, and quality degradation due to the moisture adhered on a wafer can be avoided.

Even when a gas curtain is formed by the shield gas curtain apparatus provided in the EFEM according to the present invention, it is conceivable that the humidity in the purge container may somewhat increase after the internal space of the purge container is brought into communication with that of the wafer transport chamber from the level at that time. The increased humidity, however, will reach a peak at some point in time and the peak level will be smaller than the case where a gas curtain is not formed by the shield gas curtain apparatus, which is small enough to prevent and suppress adherence of moisture onto a wafer. In view of this point, according to the EFEM of the present invention, during a process of bottom purging to reduce the humidity in the purge container with the bottom purge apparatus while the internal space of the purge container is not in communication with that of the wafer transport chamber, wafer transportation can be started when the humidity reaches the same level as the above-described peak level by bringing the internal space of the purge container into communication with that of the wafer transport chamber. In this way, time needed from when bottom purging is started for the purge container to when the internal space of the purge container is brought into communication with that of the wafer transport chamber can be reduced, leading to tact time reduction, and consequently, an improved efficiency of wafer processing.

The present invention relates to a load port adjacent to the wafer transport chamber, the load port including a bottom purge apparatus and a shield gas curtain apparatus. The bottom purge apparatus is capable of replacing a gaseous atmosphere in the purge container with a purge gas composed of nitrogen or dry air from the bottom side of the purge container. The shield gas curtain apparatus is an apparatus that forms a gas curtain capable of shielding an opening when the internal space of the purge container, in which at least humidity is reduced to a predetermined value by supplying the purge gas from the bottom purge apparatus, is brought into communication with the internal space of the wafer transport chamber through the opening, the gas curtain being formed of a shield curtain gas composed of nitrogen or dry air blown immediately downward or obliquely downward such that the gas diverges from the purge container, from a location near the opening and being closer to the wafer transport chamber than the opening at the same height as or a higher height than an upper edge of the opening.

The load port has advantages similar to the EFEM. Specifically, it is possible to perform purging leading to a high maximum concentration of a gaseous atmosphere by the bottom purge apparatus so as to maintain a low humidity at or below a predetermined value in the purge container. Even when the internal space of the purge container is in communication with that of the wafer transport chamber, a gas curtain that shields the opening can be formed by the shield gas curtain apparatus to prevent and suppress the entrance of the gaseous atmosphere in the wafer transport chamber into the purge container. Consequently, even after the internal space of the purge container is in communication with that of the wafer transport chamber, a low humidity can be maintained in the purge container and a rapid increase in the humidity in the purge container can be avoided. According to the load port of the present invention, which is capable of thus maintaining a low humidity in the purge container, adherence of moisture onto a wafer in the purge container can be prevented and suppressed, and quality degradation due to the moisture adhered on a wafer can be avoided.

Even when a gas curtain is formed by the shield gas curtain apparatus provided in the load port according to the present invention, it is conceivable that the humidity in the purge container may somewhat increase after the internal space of the purge container is brought into communication with that of the wafer transport chamber from the level at that time. The increased humidity, however, will reach a peak at some point in time and the peak level will be smaller than the case where a gas curtain is not formed by the shield gas curtain apparatus, which is small enough to prevent and suppress adherence of moisture onto a wafer. In view of this point, according to the load port of the present invention, during a process of bottom purging to reduce the humidity in the purge container with the bottom purge apparatus while the internal space of the purge container is not in communication with that of the wafer transport chamber, wafer transportation can be started when the humidity reaches the same level as the above-described peak level by bringing the internal space of the purge container into communication with that of the wafer transport chamber. In this way, time needed from when bottom purging is started for the purge container to when the internal space of the purge container is brought into communication with that of the wafer transport chamber can be reduced, leading to tact time reduction, and consequently, an improved efficiency of wafer processing.

Furthermore, according to the EFEM and the load port of the present invention, a low oxygen concentration in the purge container can also be maintained, the oxygen being a cause of wafer oxidation.

Note that “purge container” of the present invention includes containers in general that is portable with a wafer contained therein and has a space to be purged therein, one example of which includes a FOUP.

According to the present invention, an EFEM and a load port can be provided, which include a bottom purge apparatus for bottom purging and a shield gas curtain apparatus that forms a gas curtain, and operate these apparatuses to prevent and suppress a rapid increase in the humidity or the oxygen concentration in a purge container occurring immediately after the internal space of the purge container is brought into communication with that of a wafer transport chamber, so that quality degradation due to the moisture adhered on a wafer can be avoided.

### BRIEF DESCRIPTION OF THE DRAWINGS

FIG. 1 schematically illustrates a relative positional relation of an EFEM and peripheral apparatuses, and airflows in a FOUP and a wafer transport chamber with the doors closed, according to a first embodiment of the present invention;

FIG. 2 is a graphical representation illustrating a humidity variation in the FOUP when a shield gas curtain apparatus is not operated in the first embodiment;

FIG. 3 schematically illustrates airflows in the FOUP and the wafer transport chamber with the doors opened in the first embodiment;

FIG. 4 is a graphical representation illustrating a humidity variation in the FOUP when the shield gas curtain apparatus is operated in the first embodiment;

FIG. 5 is a graphical representation corresponding to FIG. 4, illustrating the fact that the door opening timing can be set earlier in the first embodiment;

FIG. 6 schematically illustrates a relative positional relation of a load port and peripheral apparatuses and airflows in a FOUP and a wafer transport chamber with the doors closed, according to a second embodiment of the present invention; and

FIG. 7 schematically illustrates airflows in the FOUP and the wafer transport chamber with the doors opened in the second embodiment.

### DETAILED DESCRIPTION OF THE PREFERRED EMBODIMENTS

A first embodiment of the present invention will now be described with reference to drawings.

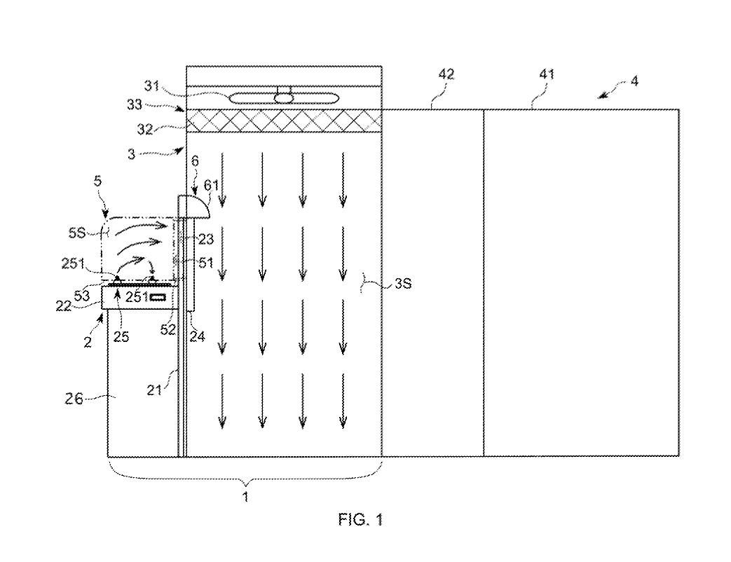

As illustrated in FIG. 1, an EFEM 1 according to the embodiment is composed of a load port 2 and a wafer transport chamber 3 adjacent to each other in a common clean room. FIG. 1 is a diagram of the load port 2 and its surroundings when viewed from one side, and schematically illustrates a relative positional relation of the load port 2 and the wafer transport chamber 3, as well as a relative positional relation of the EFEM 1, which is composed of the load port 2 and the wafer transport chamber 3, a semiconductor manufacturing apparatus 4, and a FOUP 5, which is a purge container.

The FOUP 5 illustrated by a long dashed double-short-dashed line in FIG. 1 houses a plurality of wafers therein, is configured to allow the wafers to be exchanged through a carrying-in/carrying-out port 51 formed in a front face, and includes a lid 52 capable of opening and closing the carrying-in/carrying-out port 51. Such a FOUP is well known and further description will be omitted. Note that the front face of the FOUP 5 in the embodiment refers to a surface that faces a door section 24 of the load port 2 when the FOUP 5 is placed on the load port 2. A bottom 53 of the FOUP 5 has purge ports provided at predetermined locations. Each port is mainly composed of, for example, a hollow cylindrical grommet seal fit in a purge through hole formed in the bottom 53 of the FOUP 5. A valve that switches from a closed state to an opened state by the injection pressure or discharge pressure of gas (to be described later) such as nitrogen, inert gas, or dry air (note that nitrogen gas is used in the embodiment and may be referred to as “purge gas” in the description below) is provided in the grommet seal.

The semiconductor manufacturing apparatus 4 includes, for example, a semiconductor manufacturing apparatus main body 41 that is located relatively farther from the wafer transport chamber 3 and a load lock chamber 42 that is located relatively closer to the wafer transport chamber 3. In the embodiment, the load port 2, the wafer transport chamber 3, the load lock chamber 42, and the semiconductor manufacturing apparatus main body 41 are arranged in close contact with each other in this order.

The wafer transport chamber 3 is provided with a wafer transport robot (not shown) capable of transporting a wafer between the FOUP 5 and the semiconductor manufacturing apparatus in an internal space 3S. The EFEM 1 of the embodiment is provided with a fan filter unit (FFU) 33, which is composed of a fan 31 and a filter 32 as a unit, in the upper portion (ceiling) of the wafer transport chamber 3. The FFU 33 blows clean air (dry air) continuously or as necessary while the EFEM 1 is in operation, and guides the air to flow downward from the top in the wafer transport chamber interior 3S so as to maintain a high cleanliness in the wafer transport chamber interior 3S.

The load port 2 is used to open and close a lid 52 of the FOUP 5 in a close contact state and allow a wafer to be exchanged between the FOUP interior 5S and the wafer transport chamber interior 3S. The load port 2 includes a substantially rectangular and vertically arranged frame 21, a table 22 horizontally provided on the frame 21, an opening 23 that defines an opening lower edge in the frame 21 at a height substantially the same as the table 22 and can communicate with the wafer transport chamber interior 3S, a door section 24 that opens and closes the opening 23, and a bottom purge apparatus 25 that injects a purge gas into the FOUP interior 5S and is capable of replacing a gaseous atmosphere in the FOUP interior 5S with the purge gas such as nitrogen. In this embodiment, the frame 21 is disposed such that the frame 21 is in contact with the wafer transport chamber 3 (see FIG. 1). The table 22 is supported by a support base 26.

The door section 24 provided on the frame 21 with the FOUP 5 placed on the table 22 is movable between an opened position where the door section 24 in close contact with the lid 52 provided on the front face of the FOUP 5 pushes the lid 52 to open the carrying-in/carrying-out port 51 and the opening of the FOUP 5 at the same time, and a closed position where the door section 24 closes the carrying-in/carrying-out port 51 and the opening of the FOUP 5. As a door elevating mechanism (not shown) for at least vertically moving the door section 24 between the opened position and the closed position, any known type of mechanism can be used.

The bottom purge apparatus 25 includes a plurality of bottom purge nozzles 251 arranged at predetermined locations with a distal end (upper end) exposed on a top face of the table 22, and causes each of the plurality of bottom purge nozzles 251 to function as an injection bottom purge nozzle that injects purge gas or a discharge bottom purge nozzle that discharges a gaseous atmosphere in the FOUP interior 5S. The ratios of injection bottom purge nozzles and discharge bottom purge nozzles to all the bottom purge nozzles 251 may be equal or one of the ratios may be higher than the other.

The plurality of bottom purge nozzles 251 can be attached to appropriate positions on the table 22 corresponding to the positions of the ports provided on the bottom 53 of the FOUP 5. Each bottom purge nozzle 251 (injection bottom purge nozzle or discharge bottom purge nozzle) has a valve function for regulating backflow of gas. Note that, of the plurality of ports provided on the bottom 53 of the FOUP 5, the port that contacts an injection bottom purge nozzle 251 functions as an injection port, while the port that contacts a discharge bottom purge nozzle 251 functions as a discharge port.

In this embodiment, as illustrated in FIG. 1, with the FOUP 5 placed on the table 22, bottom purge nozzles 251 that are located relatively farther in the front-back direction of FOUP 5 from the opening 23 functions as injection bottom purge nozzles, and bottom purge nozzles 251 that are located relatively closer to the opening 23 functions as discharge bottom purge nozzles. In FIG. 1, airflows in the FOUP interior 5S are schematically illustrated by arrows while the lid 52 of the FOUP 5 and the door section 24 of the load port 2 are closed (door closed state).

The bottom purge nozzles 25 may be configured to be movable up and down between a standby position where the distal end (upper end) thereof is not in contact with the port of the FOUP 5 and a purge position where the distal end (upper end) thereof can contact the port of the FOUP 5. Mounted as a unit at a plurality of predetermined locations in the table 22 of the load port 2 (for example, near four corners of the table 22), the bottom purge nozzles 251 function as a bottom purge apparatus 25 capable of replacing a gaseous atmosphere in the FOUP interior 5S placed on the table 22 with the purge gas.

The usage and action of the load port 2 including thus configured bottom purge apparatus 25 implemented in the table 22 will now be described.

First, the FOUP 5 is transported by a transport apparatus such as an OHT (not shown) to the load port 2 and is placed on the table 22. The positioning protrusions for example, provided on the table 22 fit in the positioning recesses of the FOUP 5 to allow the FOUP 5 to be placed at a predetermined normal position on the table 22. A seating sensor (not shown) that detects whether or not the FOUP 5 is placed at a predetermined position on the table 22 may be configured to detect that the FOUP 5 is placed at the normal position on the table 22. The bottom purge nozzles 251 can be positioned at the standby position until the FOUP 5 is placed on the table 22 of the load port 2 to avoid inadvertent contact of the bottom purge nozzles 251 with the port of the FOUP 5.

Then the load port 2 of the embodiment moves the bottom purge nozzles 251 up from the standby position to the purge position to contact the lower end of the port and brings gas flow paths formed in the bottom purge nozzles 251 into communication with the internal space of the port in the height direction. In this state, the load port 2 of the embodiment injects a purge gas supplied from a source (not shown) into the FOUP interior 5S through the gas flow paths of the purge nozzles and the internal space of the port, discharges a gas filling the FOUP interior 5S to outside the FOUP 5 through the discharge port and discharge bottom purge nozzles 251. Airflows in the FOUP interior 5S at this time are schematically illustrated by arrows in FIG. 1. Note that it is also possible to start discharge in advance of injection, discharge a certain amount of air in the FOUP interior 5S to outside the FOUP 5, and perform injection under reduced pressure.

The EFEM 1 according to the embodiment may start bottom purging immediately after the FOUP 5 is received from a transport apparatus such as an OHT onto the table 22 of the load port 2. The bottom purging reduces the humidity and the oxygen concentration in the FOUP interior 5S to or below a predetermined value in a short time, respectively, so that the environment around wafers in the FOUP interior 5S can be a lower humidity and lower oxygen environment than that before the start of bottom purging. In this way, with the EFEM 1 according to the embodiment, the bottom purging by means of the bottom purge apparatus 25 provided in the load port 2 can be effective to maintain a higher value of filling (the degree of replacement) with purge gas in the FOUP interior 5S than the front purging and to reduce the humidity and the oxygen concentration in the FOUP interior 5S to or below a predetermined value, respectively.

After the humidity and the oxygen concentration in the FOUP interior 5S are reduced to or below a predetermined value by performing the bottom purging as described above, the lid 52 of the FOUP 5 is opened at the door section 24 of the load port 2 to bring the internal space 5S of the FOUP 5 into communication with the internal space of the semiconductor manufacturing apparatus 4 through the carrying-in/carrying-out port 51 of the load port 2 and the opening 23 of the load port 2. In this state, wafers in the FOUP interior 5S are sequentially expelled into the semiconductor manufacturing apparatus 4 by the wafer transport robot located in the wafer transport chamber interior 3S.

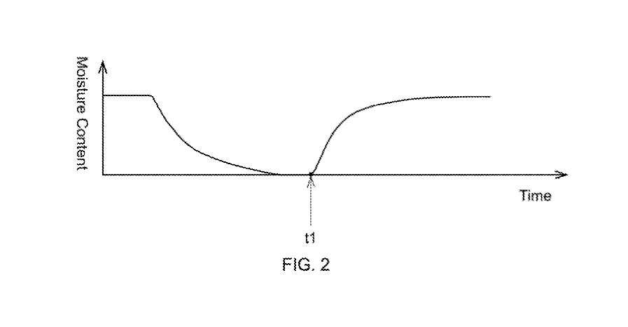

When the lid 52 of the FOUP 5 is opened at the door section 24 of the load port 2 to bring the internal space 5S of the FOUP 5 into communication with the internal space of the semiconductor manufacturing apparatus 4 through the opening 23 of the load port 2 (hereinafter referred to as “door opening time point”), the gaseous atmosphere in the wafer transport chamber interior 3S enters the FOUP interior 5S and may cause a rapid increase in the humidity and the oxygen concentration in the FOUP interior 5S after the door opening time point (FIG. 2 illustrates a humidity variation by a solid line).

In order to avoid such a situation, the EFEM 1 according to the embodiment further includes a shield gas curtain apparatus 6 that forms a gas curtain capable of shielding the opening 23 of the load port 2. The shield gas curtain apparatus 6 includes a shield curtain gas blow-off section 61 that blows a shield curtain gas composed of nitrogen or dry air immediately downward at a location near the opening 23 of the load port 2 and being closer to the wafer transport chamber 3 than the opening 23 at a higher height than an upper edge of the opening 23. The shield curtain gas blown from the shield curtain gas blow-off section 61 forms a gas curtain capable of shielding the opening 23. The lower end (distal end) of the shield curtain gas blow-off section 61 may be set at the same height as the upper edge of the opening 23. The source (not shown) of the shield curtain gas may be the same source as the purge gas or may be separate from that of the purge gas. The source of the shield gas and the shield curtain gas blow-off section 61 are connected with each other through suitable pipes and joints.

Examples of the shield curtain gas blow-off section 61 include one made up of a plurality of nozzles arranged at a predetermined interval over an area larger than the width dimension of the opening 23 (nozzle type), and one made up of a single air outlet whose width dimension is larger than the width dimension of the opening 23 (blow type). When the shield curtain gas blow-off section 61 is of a nozzle type, the shield curtain gas blown from each of the nozzles forms a jet stream. On the other hand, when the shield curtain gas blow-off section 61 is of a blow type, the shield curtain gas blown from the single air outlet forms a planar flow along a blow direction.

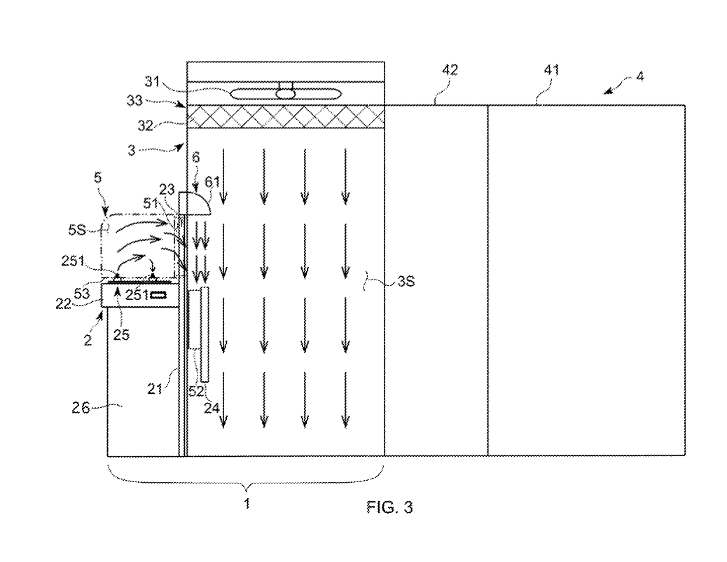

In the shield gas curtain apparatus 6 of the embodiment, as illustrated in FIG. 3, the flow rate is set so that the shield curtain gas blown from the shield curtain gas blow-off section 61 reaches down beyond the opening lower edge of the opening 23. The airflow of such a shield curtain gas is separated from the airflow generated by the FFU 33.

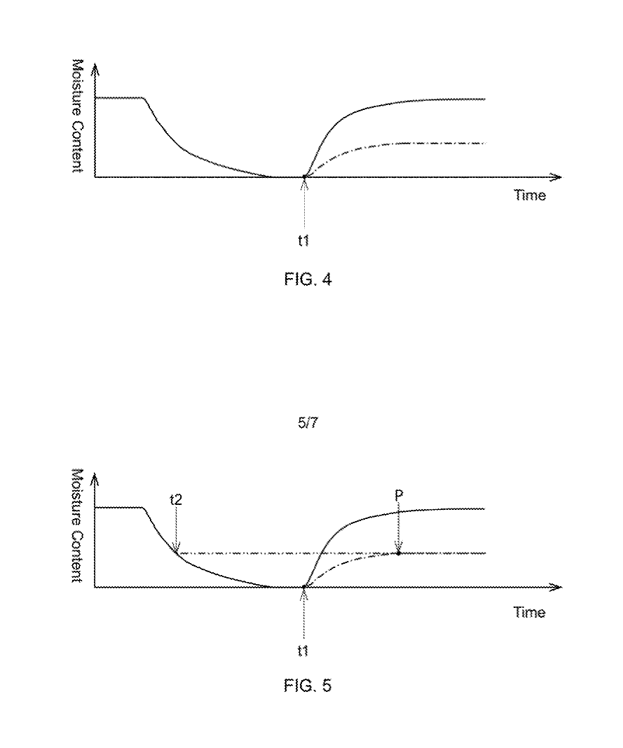

The shield gas curtain apparatus 6 is then operated at the door opening time point or at a time point earlier than the door opening time point to form a shield gas curtain that shields the opening 23 of the load port 2. Accordingly, it is possible to prevent the gaseous atmosphere in the wafer transport chamber interior 3S from entering the FOUP interior 5S after the door opening time point, and to prevent and suppress a rapid increase in the humidity or the oxygen concentration in the FOUP interior 5S occurring immediately after the door opening time point. FIG. 4 illustrates, by a long dashed short-dashed line, a humidity variation in the FOUP interior 5S when the shield gas curtain apparatus 6 is operated after bottom purging is performed by the bottom purge apparatus 25 in a door closed state. Note that the humidity variation in the FOUP interior 5S indicated in by a long dashed short-dashed line FIG. 4 represents when the bottom purging performed by the bottom purge apparatus 25 is continued after the door opening time point.

As described above, the load port 2 according to the embodiment includes a shield gas curtain apparatus 6 that forms a gas curtain capable of shielding the opening 23 of the load port 2 when the internal space 5S of the FOUP 5 which is a purge container, in which at least humidity is reduced to a predetermined value (in FIG. 4, the “predetermined value” is zero or substantially zero) by supplying the purge gas from the bottom purge apparatus 25, is brought into communication with the internal space 3S of the wafer transport chamber 3 through the opening 23 (time t1 in FIG. 4), the gas curtain being formed of a shield curtain gas composed of nitrogen or dry air blown immediately downward from a location near the opening 23 and being closer to the wafer transport chamber 3 than the opening 23 at the same height as or a higher height than an upper edge of the opening 23. As a result, in the door closed state where the internal space 5S of the FOUP 5 is not in communication with the internal space 3S of the wafer transport chamber 3, the humidity in the internal space 5S of the FOUP 5 can be reduced to or below the predetermined value by the bottom purge apparatus 25. Even in the door open state where the internal space 5S of the FOUP 5 is in communication with the internal space 3S of the wafer transport chamber 3, it is possible to prevent and suppress the gaseous atmosphere in the wafer transport chamber interior 3S from entering a low humidity and low oxygen environment of the FOUP interior 5S by forming a gas curtain by the shield gas curtain apparatus 6. In addition, after the door opening time point (for example, time t1 indicated in FIG. 4), the humidity in the FOUP interior 5S can be maintained in a range (allowable humidity range) low enough to prevent and suppress adherence of moisture onto a wafer in the FOUP interior 5S, so that quality degradation due to the moisture adhered on a wafer can be

As illustrated in FIG. 4, although the humidity in the FOUP interior 5S may somewhat increase after the door opening time point even when a gas curtain is formed by the shield gas curtain apparatus 6, a peak will be reached at some point in time and the peak value P will not be exceeded. When the peak value P represents a humidity enough to prevent and suppress adherence of moisture onto a wafer in the FOUP interior 5S, in view of this point and as illustrated in FIG. 5, during a process of bottom purging by means of the bottom purge apparatus 25 to gradually reduce the humidity in the FOUP interior 5S with the lid 52 of the FOUP 5 closed, wafer transportation can be started at a time t2 when the humidity reaches the same level as the above-described peak value P by opening the lid 52 of the FOUP 5 with the door section 24 of the load port 2 so as to bring the FOUP 5 into communication with the internal space 3S of the wafer transport chamber 3 through the opening 23 of the load port 2. Consequently, the peak value P can be considered as a “predetermined value” of the present invention. When the bottom purging and the shield curtain gas blowing are performed at the same time, a peak value P at which the humidity in the FOUP 5 reaches the highest can be determined in advance. Then, the bottom purging by means of the bottom purge apparatus 25 is performed with the lid 52 of the FOUP 5 closed to reduce the humidity in the FOUP interior 5S to the peak value P, instead of reducing it to zero or approximately zero. In this state, when the bottom purging and the shield curtain gas blowing are continued after the time point t2 when the peak value P has been reached, the humidity in the FOUP interior 5S will no longer increase further. Then, the time point t2, at which the humidity in the FOUP interior 5S is reduced to the peak value P, can be selected as a timing for opening the lid 52 of the FOUP 5, instead of the time point t1, at which the humidity is reduced to zero or approximately zero with the lid 52 of the FOUP 5 closed. As a result, time needed from when the FOUP 5 is received on the table 22 at the load port 2 from a transport apparatus such as an OHT to when the lid 52 of the FOUP 5 is opened can be reduced, leading to tact time reduction, and consequently, an improved efficiency of wafer processing.

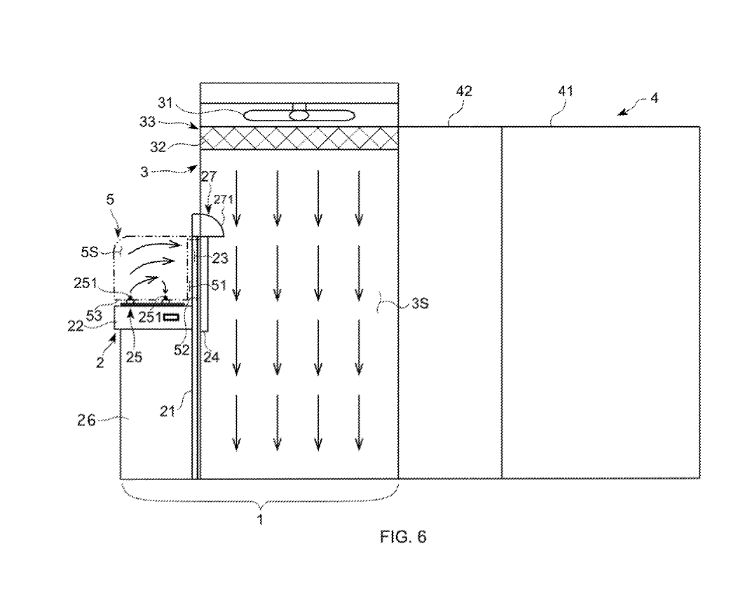

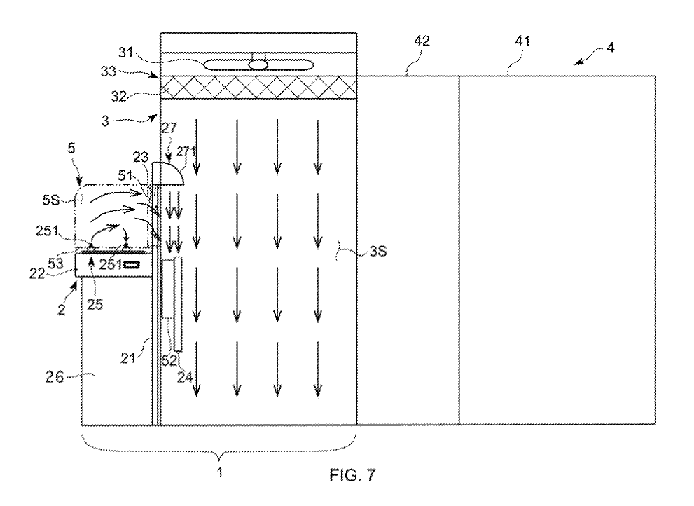

Another embodiment (hereinafter referred to as a second embodiment) different from the embodiment described above (which is a first embodiment) will now be described with reference to FIGS. 6 and 7 among others.

The second embodiment is different from the first embodiment in that a shield gas curtain apparatus 27 is provided on the load port 2. Accordingly, although the configuration of the load port 2 will be detailed below, description on the wafer transport chamber 3 and the semiconductor manufacturing apparatus 4 will be omitted.

As illustrated in FIGS. 6 and 7, the load port 2 according to the embodiment is used to open and close a lid 52 of the FOUP 5 in a close contact state and allow a wafer to be exchanged between the FOUP interior 5S and the wafer transport chamber interior 3S. The load port 2 includes a substantially rectangular and vertically arranged frame 21, a table 22 horizontally provided on the frame 21, an opening 23 that defines an opening lower edge in the frame 21 at a height substantially the same as the table 22 and can communicate with the wafer transport chamber interior 3S, a door section 24 that opens and closes the opening 23, a bottom purge apparatus 25 that injects a purge gas into the FOUP interior 5S and is capable of replacing a gaseous atmosphere in the FOUP interior 5S with the purge gas such as nitrogen, a support base 26 supporting the table 22, and a shield gas curtain apparatus 27 that forms a gas curtain capable of shielding the opening 23.

The door section 24 provided on the frame 21 is with the FOUP 5 placed on the table 2 movable between an opened position where the door section 24 in close contact with the lid 52 provided on the front face of the FOUP 5 pushes the lid 52 to open the carrying-in/carrying-out port 51 and the opening of the FOUP 5 at the same time and a closed position where the door section 24 closes the carrying-in/carrying-out port 51 and the opening of the FOUP 5. As a door elevating mechanism (not shown) for at least vertically moving the door section 24 between the opened position and the closed position, any known type of mechanism can be used.

The bottom purge apparatus 25 includes a plurality of bottom purge nozzles 251 arranged at predetermined locations with an upper end (distal end) exposed on a top face of the table 22, and causes each of the plurality of bottom purge nozzles 251 to function as an injection bottom purge nozzle that injects purge gas or a discharge bottom purge nozzle that discharges a gaseous atmosphere in the FOUP interior 5S. The ratios of injection bottom purge nozzles and discharge bottom purge nozzles to all the bottom purge nozzles 251 may be equal or one of the ratios may be higher than the other.

The plurality of bottom purge nozzles 251 can be attached to appropriate positions on the table 22 corresponding to the positions of the ports provided on the bottom 53 of the FOUP 5. Each bottom purge nozzle 251 (injection bottom purge nozzle or discharge bottom purge nozzle) has a valve function for regulating backflow of gas and can be brought into contact with ports provided on the bottom 53 of the FOUP 5. Note that, of the plurality of ports provided on the bottom 53 of the FOUP 5, the port that contacts an injection bottom purge nozzle functions as an injection port, while the port that contacts a discharge bottom purge nozzle functions as a discharge port.

In this embodiment, as illustrated in FIG. 6, bottom purge nozzles 251 that are located relatively farther in the front-back direction of FOUP from the opening 23 function as injection bottom purge nozzles, and bottom purge nozzles 251 that are located relatively closer to the opening 23 function as discharge bottom purge nozzles. In FIG. 6, airflows in the FOUP interior 5S are schematically illustrated by arrows while the lid 52 of the FOUP 5 and the door section 24 of the load port 2 are closed (door closed state).

The bottom purge nozzles 251 may be configured to be movable up and down between a standby position where the distal end (upper end) thereof is not in contact with the port of the FOUP 5 and a purge position where the distal end (upper end) thereof can contact the port of the FOUP 5. Mounted as a unit at a plurality of predetermined locations in the table 22 of the load port 2 (for example, near four corners of the table 22), the bottom purge nozzles 251 function as a bottom purge apparatus 25 capable of replacing a gaseous atmosphere in the FOUP interior 5S placed on the table 22 with the purge gas.

The shield gas curtain apparatus 27 includes a shield curtain gas blow-off section 271 that blows a shield curtain gas composed of nitrogen or dry air immediately downward at a location near the opening 23 of the load port 2 and being closer to the wafer transport chamber 3 than the opening 23 at a higher height than an upper edge of the opening 23. The shield curtain gas blown from the shield curtain gas blow-off section 271 forms a gas curtain capable of shielding the opening 23. The lower end (distal end) of the shield curtain gas blow-off section 271 may be set at the same height as the upper edge of the opening 23. The source (not shown) of the shield curtain gas may be the same source as the purge gas or may be separate from that of the purge gas. The source of the shield gas and the shield curtain gas blow-off section 271 are connected with each other through suitable pipes and joints.

Examples of the shield curtain gas blow-off section 271 include one made up of a plurality of nozzles arranged at a predetermined interval over an area larger than the width dimension of the opening 23 (nozzle type), and one made up of a single air outlet whose width dimension is larger than the width dimension of the opening 23 (blow type). The shield curtain gas blow-off section 271 of a nozzle type causes the shield curtain gas blown from each of the nozzles to form a jet stream. On the other hand, the shield curtain gas blow-off section 271 of a blow type causes the shield curtain gas blown from the single air outlet to form a planar flow along a blow direction.

In the shield gas curtain apparatus 27 of the embodiment, as illustrated in FIG. 7, the flow rate is set so that the shield curtain gas blown from the shield curtain gas blow-off section 271 reaches down beyond the opening lower edge of the opening 23. The airflow of such a shield gas curtain is separated from the airflow generated by the FFU 33.

The usage and action of the load port 2 including the bottom purge apparatus 25 and the shield gas curtain apparatus 27 as described above implemented therein will now be described.

First, the FOUP 5 is transported by a transport apparatus such as an OHT (not shown) to the load port 2 and is placed on the table 22. The positioning protrusions provided on the table 22 fit in the positioning recesses of the FOUP 5 to allow the FOUP 5 to be placed at a predetermined normal position on the table 22. A seating sensor (not shown) that detects whether or not the FOUP 5 is placed at a predetermined position on the table 22 may be configured to detect that the FOUP 5 is placed at the normal position on the table 22. The bottom purge nozzles 251 are positioned at the standby position until the FOUP 5 is placed on the table 22 of the load port 2 to avoid inadvertent contact of the bottom purge nozzles 251 with the port of the FOUP 5.

Then the load port 2 according to the embodiment moves the bottom purge nozzles 251 up from the standby position to the purge position to contact the lower end of the port and brings gas flow paths formed in the bottom purge nozzles 251 into communication with the internal space of the port in the height direction. In this state, the load port 2 according to the embodiment injects a purge gas supplied from a source (not shown) into the FOUP interior 5S through the gas flow paths of the purge nozzles and the internal space of the port, discharges a gas filling the FOUP interior 5S to outside the FOUP 5 through the discharge port and discharge bottom purge nozzles 251. Airflows in the FOUP interior 5S at this time are schematically illustrated by arrows in FIG. 6. Note that it is also possible to start discharge in advance of injection, discharge a certain amount of air in the FOUP interior 5S to outside the FOUP 5, and perform injection under reduced pressure.

The load port 2 according to the embodiment may start bottom purging immediately after the FOUP 5 is received from a transport apparatus such as an OHT onto the table 22. The bottom purging reduces the humidity and the oxygen concentration in the FOUP interior 5S to or below a predetermined value in a short time, respectively, so that the environment around wafers in the FOUP interior 5S can be a lower humidity environment than that before the start of bottom purging. In this way, with the load port 2 according to the embodiment, the bottom purging by means of the bottom purge apparatus 25 can be effective to maintain a higher value of filling (the degree of replacement) with purge gas in the FOUP interior 5S than the front purging, and to reduce the humidity and the oxygen concentration in the FOUP interior 5S to or below a predetermined value, respectively.

After the humidity and the oxygen concentration in the FOUP interior 5S are reduced to or below a predetermined value by performing the bottom purging as described above, the lid 52 of the FOUP 5 is opened at the door section 24 of the load port 2 to bring the internal space 5S of the FOUP 5 into communication with the internal space of the semiconductor manufacturing apparatus 4 through the carrying-in/carrying-out port 51 of the load port 2 and the opening 23 of the load port 2. In this state, wafers in the FOUP interior 5S are sequentially expelled into the semiconductor manufacturing apparatus 4 by the wafer transport robot located in the wafer transport chamber interior 3S.

In the load port 2 according to the embodiment, the shield gas curtain apparatus 27 is then operated at the door opening time point or at a time point earlier than the door opening time point to form a shield gas curtain that shields the opening 23 of the load port 2, so as to prevent the gaseous atmosphere in the wafer transport chamber interior 3S from entering the FOUP interior 5S after the door opening time point, and to prevent and suppress a rapid increase in the humidity or the oxygen concentration in the FOUP interior 5S occurring immediately after the door opening time point. FIG. 4 illustrates, by a long dashed short-dashed line, a humidity variation in the FOUP interior 5S when the shield gas curtain apparatus 27 is operated after bottom purging is performed by the bottom purge apparatus 25 in a door closed state. The humidity variation in the FOUP interior 5S indicated by a long dashed short-dashed line in FIG. 4 represents when the bottom purging performed by the bottom purge apparatus 25 is continued after the door opening time point.

As described above, the EFEM 1 and the load port 2 according to the embodiment includes a shield gas curtain apparatus 27 that forms a gas curtain capable of shielding the opening 23 of the load port 2 when the internal space 5S of the FOUP 5 which is a purge container, in which at least humidity is reduced to a predetermined value (in FIG. 4, the “predetermined value” is zero or substantially zero) by supplying the purge gas from the bottom purge apparatus 25, is brought into communication with the internal space 3S of the wafer transport chamber 3 through the opening 23, the gas curtain being formed of a shield curtain gas composed of nitrogen or dry air blown immediately downward from a location near the opening 23 and being closer to the wafer transport chamber 3 than the opening 23 at the same height as or a higher height than an upper edge of the opening 23. As a result, in the door closed state where the internal space 5S of the FOUP 5 is not in communication with the internal space 3S of the wafer transport chamber 3, the humidity in the internal space 5S of the FOUP 5 can be reduced to or below the predetermined value by the bottom purge apparatus 25. Even in the door open state where the internal space 5S of the FOUP 5 is in communication with the internal space 3S of the wafer transport chamber 3, it is possible to prevent and suppress the gaseous atmosphere in the wafer transport chamber interior 3S from entering a low humidity and low oxygen environment of the FOUP interior 5S by forming a gas curtain by the shield gas curtain apparatus 27. In addition, after the door opening time point (for example, time t1 indicated in FIG. 4), the humidity in the FOUP interior 5S can be maintained in a range (allowable humidity range) low enough to prevent and suppress adherence of moisture onto a wafer, so that quality degradation due to the moisture adhered on a wafer can be avoided.

As illustrated in FIG. 4, although the humidity in the FOUP interior 5S may somewhat increase after the door opening time point even when a gas curtain is formed by the shield gas curtain apparatus 27, a peak will be reached at some point in time and the peak value P will not be exceeded. When the peak value P represents a humidity enough to prevent and suppress adherence of moisture onto a wafer in the FOUP interior 5S, in view of this point and as illustrated in FIG. 5, during a process of bottom purging by means of the bottom purge apparatus 25 to gradually reduce the humidity in the FOUP interior 5S with the lid 52 of the FOUP 5 closed, wafer transportation can be started at a time t2 when the humidity reaches the same level as the above-described peak value P by opening the lid 52 of the FOUP 5 with the door section 24 of the load port 2 so as to bring the FOUP 5 into communication with the internal space 3S of the wafer transport chamber 3 through the opening 23 of the load port 2. Consequently, the peak value P can be considered as a “predetermined value” of the present invention. When the bottom purging and the shield curtain gas blowing are performed at the same time, a peak value P at which the humidity in the FOUP interior 5S reaches the highest can be determined in advance. Then, the bottom purging by means of the bottom purge apparatus 25 is performed with the lid 52 of the FOUP 5 closed to reduce the humidity in the FOUP interior 5S to the peak value P, instead of reducing it to a predetermined value of zero or approximately zero. In this state, when the bottom purging and the shield curtain gas blowing are continued after the time point t2 when the peak value P has been reached, the humidity in the FOUP interior 5S will no longer increase further. Then, the time point t2, at which the humidity in the FOUP interior 5S is reduced to the peak value P, can be selected as a timing for opening the lid 52 of the FOUP 5, instead of the time point t1, at which the humidity is reduced to zero or approximately zero with the lid 52 of the FOUP 5 closed. As a result, time needed from when the FOUP 5 is received on the table 22 at the load port 2 from a transport apparatus such as an OHT to when the lid 52 of the FOUP 5 is opened can be reduced, leading to tact time reduction, and consequently, an improved efficiency of wafer processing.

In any of the embodiments described above (the first and second embodiments), each wafer transferred into the semiconductor manufacturing apparatus 4 is then subjected to a semiconductor manufacturing process by the semiconductor manufacturing apparatus main body 41. The wafers having undergone the semiconductor manufacturing process by the semiconductor manufacturing apparatus main body 41 are sequentially stored in the FOUP 5. When all the wafers have undergone the semiconductor manufacturing process and are stored in the FOUP 5, the door section 24 is moved from the opened position to the closed position while the door section 24 is in close contact with the lid 52 of the FOUP 5. As a result, the opening 23 of the load port 2 and the carrying-in/carrying-out port 51 of the FOUP 5 are closed, and the FOUP 5 on the table 22 is then carried out by a transport mechanism (not shown) to a next process.

Note that the present invention is not limited to the above-described embodiments. For example, although a FOUP is illustrated as a purge container in the above-described embodiments, any other container (carrier) may be used as the purge container.

Applicable shield gas curtain apparatuses may include one that forms a gas curtain capable of shielding the opening by means of a shield curtain gas blown obliquely downward such that the gas diverges from the purge container. The gas curtain formed by such a shield gas curtain apparatus can prevent and suppress the entrance of the gas in the wafer transport chamber into the purge container in the door open state. In this case, the shield curtain gas blow-off section of the shield gas curtain apparatus may also be either a nozzle type or a blow type.

The specific configuration of each section is not limited to the above embodiments, and various modifications can be made without departing from the scope of the present invention.

What is claimed is:

1. A method for manufacturing semiconductor, comprising:
providing a semiconductor manufacturing apparatus;
providing an EFEM comprising:
a wafer transport chamber;
a shield gas curtain apparatus for shielding an opening, and
a load port adjacent to the wafer transport chamber; the load port: comprising
an opening,
a table to place a purge container,
a door section for opening and closing the opening and
a bottom purge apparatus equipped with the table, the bottom purge apparatus replacing a gaseous atmosphere in a purge container with a purge gas composed of an inert gas or dry air from a bottom side of the purge container, and
a placing step for placing the purge container on the table,
a humidity reducing step for injecting the purge gas into the purge container from the bottom purge apparatus to discharge the gaseous atmosphere from the purge container to reduce humidity inside the purge container,
a gas curtain forming step for forming a shield gas curtain by operating the shield gas curtain apparatus,
a lid opening step for opening a lid of the purge container after replacing the gaseous atmosphere with the purge gas such that an internal space of the purge container is brought into communication with an internal space of the wafer transport chamber through the opening,
a wafer transporting step for expelling a wafer in the wafer transport chamber from the purge container into the semiconductor manufacturing apparatus,
a semiconductor processing step for processing the wafer in the semiconductor manufacturing apparatus,
wherein in the lid opening step the door section starts to open the lid at a timing when the humidity inside the purge container is reduced to a value to prevent and suppress adherence of moisture onto the wafer in the purge container.

2. The method for manufacturing semiconductor according to claim 1, wherein in the gas curtain forming step, the shield gas curtain apparatus starts operating to form the shield gas curtain at a door opening timing when the door section starts to open the lid in the lid opening step or at a time point earlier than the door opening timing and continues to be operated while the wafer is expelled from the purge container interior.

3. The method for manufacturing semiconductor according to claim 1, wherein the method for manufacturing semiconductor further comprising a humidity measuring step for measuring the humidity inside the purge container.

4. The method for manufacturing semiconductor according to claim 1, wherein a peak value at which the humidity in the purge container reaches the highest after opening the lid in the lid opening step is determined in advance, wherein the shield gas curtain apparatus starts operating to form the shield gas curtain at a timing when the humidity is reduced to the peak value in the gas curtain forming step.

5. The method for manufacturing semiconductor according to claim 1, wherein the shield gas curtain apparatus starts operating to form the shield gas curtain at a timing when the humidity is reduced to zero or substantially zero in the gas curtain forming step.

6. The method for manufacturing semiconductor according to claim 1, wherein the EFEM contains none of a front purge apparatus.

7. A method for manufacturing semiconductor, comprising:
providing a semiconductor manufacturing apparatus;
providing an EFEM comprising:
a wafer transport chamber;
a shield gas curtain apparatus for shielding an opening, and
a load port adjacent to the wafer transport chamber; the load port: comprising
an opening,
a table to place a purge container,
a door section for opening and closing the opening and
a bottom purge apparatus equipped with the table, the bottom purge apparatus replacing a gaseous atmosphere in a purge container with a purge gas composed of an inert gas or dry air from a bottom side of the purge container, and
a placing step for placing the purge container on the table,
a bottom purging step in which a bottom purge apparatus equipped with the table replaces the gaseous atmosphere inside the purge container with the purge gas injected into the purge container to discharge the gaseous atmosphere from the purge container,
a humidity measuring step for measuring the humidity inside the purge container
a gas curtain forming step for forming a shield gas curtain by operating the shield gas curtain apparatus,
a lid opening step for opening a lid of the purge container after replacing the gaseous atmosphere with the purge gas such that an internal space of the purge container is brought into communication with an internal space of the wafer transport chamber through the opening,
a wafer transporting step for expelling a wafer in the wafer transport chamber from the purge container into the semiconductor manufacturing apparatus,
a semiconductor processing step for processing the wafer in the semiconductor manufacturing apparatus,
wherein in the lid opening step the door section starts to open the lid at a timing when the humidity inside the purge container is reduced to a value to prevent and suppress adherence of moisture onto the wafer in the purge container

8. The method for manufacturing semiconductor according to claim 7, wherein in the gas curtain forming step, the shield gas curtain apparatus starts operating at a door opening timing when the door section starts to open the lid in the lid opening step or at a time point earlier than the door opening timing and continues to be operated while the wafers are expelled from the purge container interior.

9. The method for manufacturing semiconductor according to claim 7, wherein a peak value at which the humidity in the purge container reaches the highest after opening the lid in the lid opening step is determined in advance,
wherein the shield gas curtain apparatus starts operating at a timing when the humidity is reduced to the peak value in the bottom purging step.

10. The method for manufacturing semiconductor according to claim 7, wherein the shield gas curtain apparatus starts operating at a timing when the humidity is reduced to zero or substantially zero in the gas curtain forming step.

11. The method for manufacturing semiconductor according to claim 7, wherein the EFEM contains none of a front purge apparatus.
